(19) United States
(12) Patent Application Publication
(10) Pub. No.: US 2025/0350019 A1
(43) Pub. Date: Nov. 13, 2025

(54) ANTENNA-IN-PACKAGE

(71) Applicant: POSTECH RESEARCH AND BUSINESS DEVELOPMENT FOUNDATION, Pohang-si (KR)

(72) Inventors: Ho-Jin SONG, Pohang-si (KR); Bahramidashtaki SIROUS, Pohang-si (KR); Sungmin CHO, Pohang-si (KR)

(21) Appl. No.: 19/175,510

(22) Filed: Apr. 10, 2025

(30) Foreign Application Priority Data
May 8, 2024 (KR) 10-2024-0060721

(51) Int. Cl. H01Q 1/22; H01L 23/31; H01L 23/498

(52) U.S. Cl. CPC H01Q 1/2283; H01L 23/49816; H01L 23/49838; H01L 23/3107

(57) ABSTRACT

Disclosed is an antenna-in-package, and more particularly, an antenna-in-package using fan-out wafer level packaging. The antenna-in-package according to an embodiment includes an antenna layer including: an antenna configured to transmit and receive a wireless signal; an integrated circuit chip configured to control the antenna; and an encapsulant configured to encapsulate at least a portion of each of the antenna and the integrated circuit chip; and a redistribution layer including: an insulating layer; and a conductive pattern disposed in the insulating layer and electrically connected to the antenna or the integrated circuit chip.

### CROSS-REFERENCE TO RELATED APPLICATION

This application claims priority to and the benefit of Korean Patent Application No. 10-2024-0060721, filed on May 8, 2024, the disclosure of which is incorporated herein by reference in its entirety.

### BACKGROUND

### Field

The present disclosure relates to an antenna-in-package, and more particularly, to an antenna-in-package using fan-out wafer level packaging.

### Description of Related Art

Recently, due to the rapid increase in wireless data traffic, interest in an antenna for high-frequency wireless communication capable of utilizing a high bandwidth is increasing. Recently, as the demand for efficient, low-cost, and high-density circuits in wireless communication and millimeter wave radar systems increases, development into the integrated circuit packaging in the antenna field is also accelerating. One such solution thereof is fan-out wafer level packaging (FOWLP) in which the wire bond between the chip and the package is replaced with a waver level redistribution layer (RDL) interconnect.

When the FOWLP is applied, an integration density of a semiconductor module may be increased due to a flexible input-output spacing and low loss connection resulting from the redistribution layer. An antenna-in-package (AiP) solution in the FOWLP typically requires a planar radiator fabricated using a conductive redistribution layer pattern.

However, the planar antenna manufactured using the RDL pattern has low efficiency due to high conduction loss and considerable surface wave activity, especially at a high frequency of 100 GHz or greater. These characteristics may become a big limitation in the AiP solution.

In addition, deformation may occur in the antenna-in-package due to a mismatch in the coefficient of thermal expansion between the semiconductor chip and the molding compound that may occur during the packaging process.

### SUMMARY

A purpose of the present disclosure is to provide an antenna-in-package that overcomes the limitations of the conventional RF (Radio Frequency) FOWLP manufacturing method and improves communication performance to enable more compact and efficient integration of an antenna for a millimeter wave wireless communication system.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

A first aspect of the present disclosure provides an antenna-in-package comprising: an antenna layer including: an antenna configured to transmit and receive a wireless signal; an integrated circuit chip configured to control the antenna; and an encapsulant configured to encapsulate at least a portion of each of the antenna and the integrated circuit chip; and a redistribution layer including: an insulating layer; and a conductive pattern disposed in the insulating layer and electrically connected to the antenna or the integrated circuit chip.

In one embodiment of the first aspect, the antenna layer may further include at least one dummy chip disposed around the antenna or the integrated circuit chip and encapsulated by the encapsulant.

In one embodiment of the first aspect, the antenna and the integrated circuit chip may be electrically connected to each other via the conductive pattern.

In one embodiment of the first aspect, the conductive pattern may include a power feeding line opening-coupled to a slot disposed at a position corresponding to a position of the antenna.

In one embodiment of the first aspect, the antenna-in-package may further comprise a contact pad connected to the conductive pattern,

In one embodiment of the first aspect, the contact pad may be connected to a solder ball.

In one embodiment of the first aspect, the solder ball may be electrically connected to a substrate.

In one embodiment of the first aspect, the antenna may include a dielectric resonator antenna.

In one embodiment of the first aspect, the antenna layer may further include a through mold via electrically connected to each of the conductive pattern and the antenna.

In one embodiment of the first aspect, the antenna may be an active semiconductor chip including a power feed structure and an antenna.

In one embodiment of the first aspect, the antenna layer may include: a first layer disposed on one side of the redistribution layer and including the integrated circuit chip and the encapsulant; a metal layer disposed on one side of the first layer; and a second layer disposed on one side of the metal layer and including the antenna and the encapsulant.

In one embodiment of the first aspect, the antenna-in-package may further comprise a through mold via extending through at least a portion of the redistribution layer and the first layer and disposed at a position corresponding to a position of the antenna.

In one embodiment of the first aspect, the antenna may include an exposed area not covered with the encapsulant and exposed to an outside.

In one embodiment of the first aspect, the antenna layer may further include a parasitic antenna element disposed on the exposed area.

In one embodiment of the first aspect, the antenna layer may include: a first layer disposed on one side of the redistribution layer and including the integrated circuit chip and the encapsulant; and a second layer disposed to surround other side of the redistribution layer and at least a portion of the first layer and including the antenna and the encapsulant.

In one embodiment of the first aspect, the antenna-in-package may further comprise a contact pad connected to the conductive pattern.

In one embodiment of the first aspect, the second layer may further include an external port electrically connected to the contact pad.

A second aspect of the present disclosure provides an antenna-in-package comprising: an antenna configured to transmit and receive a wireless signal; an integrated circuit chip configured to control the antenna; and a conductive pattern electrically connected to the antenna or the integrated circuit chip.

In one embodiment of the second aspect, the conductive pattern may be disposed in an insulating layer.

In one embodiment of the second aspect, the antenna and the integrated circuit chip may be disposed in an antenna layer.

In one embodiment of the second aspect, the insulating layer and the conductive pattern may be disposed in a redistribution layer.

In one embodiment of the second aspect, the antenna-in-package may further comprise an encapsulant configured to encapsulate at least a portion of each of the antenna and the integrated circuit chip.

In one embodiment of the second aspect, the antenna-in-package may further comprise at least one dummy chip disposed around the antenna or the integrated circuit chip and encapsulated by the encapsulant.

In one embodiment of the second aspect, the antenna and the integrated circuit chip may be electrically connected to each other via the conductive pattern.

In one embodiment of the second aspect, the conductive pattern may include a power feeding line opening-coupled to a slot disposed at a position corresponding to a position of the antenna.

In one embodiment of the second aspect, the antenna-in-package may further comprise a contact pad connected to the conductive pattern.

In one embodiment of the second aspect, the contact pad may be connected to a solder ball.

In one embodiment of the second aspect, the solder ball may be electrically connected to a substrate.

In one embodiment of the second aspect, the antenna may include a dielectric resonator antenna.

In one embodiment of the second aspect, the antenna-in-package may further comprise a through mold via electrically connected to each of the conductive pattern and the antenna.

In one embodiment of the second aspect, the antenna may be an active semiconductor chip including a power feed structure and an antenna.

In one embodiment of the second aspect, the antenna layer may include: a first layer disposed on one side of the redistribution layer and including the integrated circuit chip; a metal layer disposed on one side of the first layer; and a second layer disposed on one side of the metal layer and including the antenna.

In one embodiment of the second aspect, the antenna-in-package may further comprise a through mold via extending through at least a portion of the redistribution layer and the first layer and disposed at a position corresponding to a position of the antenna.

In one embodiment of the second aspect, the antenna may include an exposed area not covered with the encapsulant and exposed to an outside.

In one embodiment of the second aspect, the antenna layer may further include a parasitic antenna element disposed on the exposed area.

In one embodiment of the second aspect, the antenna layer may include: a first layer disposed on one side of the redistribution layer and including the integrated circuit chip; and a second layer disposed to surround other side of the redistribution layer and at least a portion of the first layer and including the antenna.

In one embodiment of the second aspect, the antenna-in-package may further comprise a contact pad connected to the conductive pattern.

In one embodiment of the second aspect, the second layer may further include an external port electrically connected to the contact pad.

The antenna-in-package according to the aspects and the embodiments has following advantages.
Improved performance of millimeter wave antenna: A new AiP design utilizing a dummy chip for a millimeter wave frequency range and a dielectric structure used as a high-efficiency dielectric resonant antenna is provided. This new design overcomes the limitations of a conventional RF FOWLP manufacturing method and improves antenna performance, thereby enabling more compact and efficient integration of the antenna for a millimeter wave wireless communication system.
Improved integrated density: FOWLP is preferred due to a high integrated density of a semiconductor module, a flexible I/O spacing and low-loss connectivity. According to the aspects and the embodiments, it is important to utilize the redistribution layer that facilitates such integration, which is important in the efficiency and cost effectiveness of the wireless communication and radar system.
Reduction in manufacturing failure and package deformation: According to the aspects and the embodiments, manufacturing failure and deformation occurring during a heating process in a packaging process are reduced. Due to a high chip occupancy resulting from the dummy chip, a volume of the molding compound may be reduced, thereby minimizing deformation due to thermal expansion mismatch.
Electromagnetic interference (EMI) suppression: According to the aspects and the embodiments, an integrated circuit chip (e.g., an RFIC chip) is isolated from noise radiation and EMI, which is particularly beneficial for the performance of mm wave applications. The feed structure of the dielectric resonance antenna is designed to achieve impedance matching by ensuring strong coupling to the inner field and offsetting the antenna from the slot.
Bandwidth and gain improvement: The antenna-in-package according to the aspects and the embodiments allows for a wider bandwidth and a higher gain. This is achieved via the strategic positioning of the components and mode merging that improves UWB performance by providing a ground plane for the antenna using the through mold via (TMV) and the redistribution layer.
Dense antenna arrangement: the antenna-in-package according to the aspects and the embodiments facilitates dense antenna array integration due to a small element spacing suitable for wide angle beam steering applications. This design suppresses a grating lobe and improves a main beam gain, which is an important improvement for a wireless communication system that controls directivity.
Various feeding structures: the antenna-in-package according to the aspects and the embodiments allows for various types of feeding structures for the dielectric resonant antenna. According to the aspects and the embodiments, a power feeding element includes a microstrip line and a coaxial wave waveguide and is opening-coupled to each of slots of various shapes. According to the aspects and the embodiments, the power feeding structure is adapted according to a radiation mode, polarization, and a geometric shape of the antenna.

The effects of the present disclosure are not limited to the above-mentioned effects, and other effects as not mentioned will be clearly understood by those skilled in the art from the following detailed description.

### BRIEF DESCRIPTION OF DRAWINGS

FIG. 1 is a plan view of an antenna-in-package according to a first embodiment.

FIG. 2 is a longitudinal cross-sectional view of the antenna-in-package according to the first embodiment.

FIG. 3 is a longitudinal cross-sectional view of an antenna-in-package according to a second embodiment.

FIG. 4 is a longitudinal cross-sectional view of an antenna-in-package according to a third embodiment.

FIG. 5 is a longitudinal cross-sectional view of an antenna-in-package according to a fourth embodiment.

FIG. 6 is a longitudinal cross-sectional view of an antenna-in-package according to a fifth embodiment.

### DETAILED DESCRIPTIONS

The above-described purpose, features and advantages will be described in detail with reference to the accompanying drawings, and accordingly, embodiments of the present disclosure may be easily implemented by a person having ordinary skill in the art to which the present disclosure belongs. In describing the present disclosure, when it is determined that a detailed description of a known technology related to the present disclosure may unnecessarily obscure the gist of the present disclosure, the detailed description thereof will be omitted. Hereinafter, a preferred embodiment of the present disclosure will be described in detail with reference to the accompanying drawings. In the drawings, the same reference numerals refer to the same or similar elements.

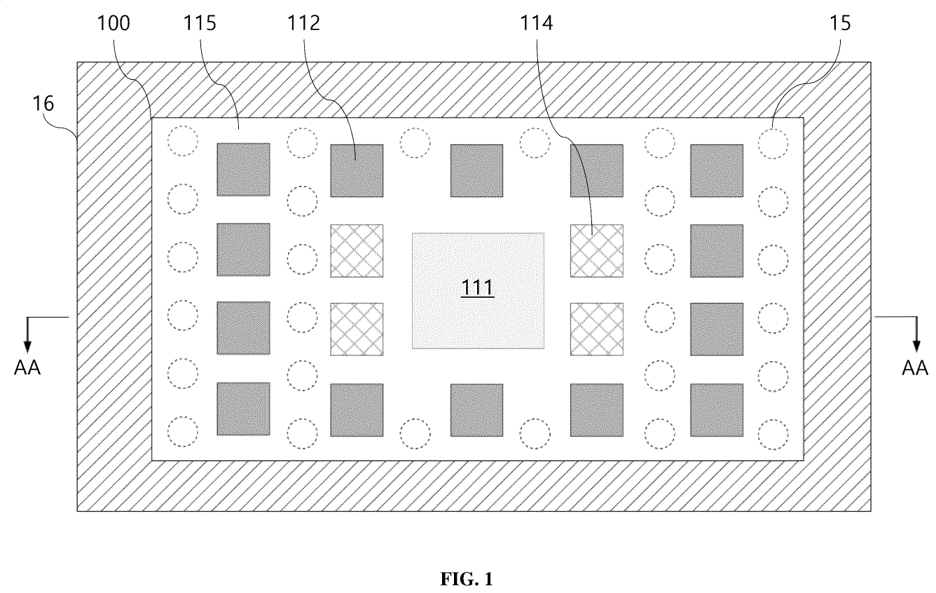

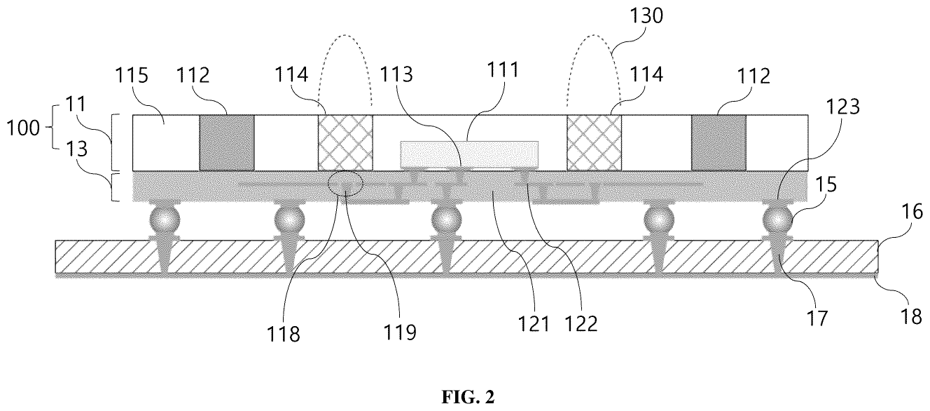

FIG. 1 is a plan view of an antenna-in-package according to a first embodiment, and FIG. 2 is a longitudinal cross-sectional view of the antenna-in-package according to the first embodiment. More specifically, FIG. 2 shows the longitudinal cross-sectional view of the antenna-in-package according to the first embodiment as cut in an AA direction shown in FIG. 1.

Referring to the drawing, an antenna-in-package 100 according to the first embodiment may include an antenna layer 11 and a redistribution layer 13.

The antenna layer 11 may include one or more antennas 114 configured to transmit and receive a wireless signal, an integrated circuit chip 111 configured to control the antenna 114, and an encapsulant 115 configured to encapsulate at least a portion of each of the antenna 114 and the integrated circuit chip 111.

In an embodiment, the antenna 114 may be a dielectric resonator antenna including a dielectric having a predetermined dielectric constant and transmitting or receiving the wireless signal under resonance of the dielectric. For example, the antenna 114 may be the dielectric resonator antenna made of undoped silicon. In another example, the antenna 114 may be the dielectric resonator antenna made of a material having a dielectric constant of 11.7 and operating in a millimeter wave band. However, the type of the antenna 114 is not limited thereto.

In an embodiment, the antenna 114 may transmit and receive a wireless signal in a radio frequency (RF) band. A shape of the antenna 114 is not particularly limited. For example, the antenna 114 may have a shape such as a cylinder, a polygonal box, a cone, a divided cylinder, a toroid, or a truncated pyramid. However, the shape of the antenna 114 is not limited thereto.

As shown in FIG. 1, the antenna-in-package 100 may include the one or more antennas 114. When the antenna-in-package 100 includes a plurality of antennas 114, the plurality of antennas 114 may be arranged according to a predetermined arrangement pattern. The plurality of antennas 114 may be arranged symmetrically or asymmetrically. The number or arrangement pattern of the antennas 114 is not particularly limited.

The integrated circuit chip 111 may control a wireless signal transmission or reception operation of the antenna 114. For example, the integrated circuit chip 111 may receive the wireless signal from the antenna 114 or may provide the wireless signal to the antenna 114.

In an embodiment, the integrated circuit chip 111 may be a radio frequency integrated circuit (RFIC) capable of receiving a wireless signal of an RF band from the antenna 114 or providing the wireless signal of the RF band to the antenna 114. However, the type of the integrated circuit chip 111 is not limited thereto, and the integrated circuit chip 111 may be a different type of a chip therefrom. In another example, the integrated circuit chip 111 may be a complementary metal oxide semiconductor (CMOS) chip for millimeter wave wireless communication.

The encapsulant 115 may protect the antenna 114 and the integrated circuit chip 111. An encapsulation form by the encapsulant is not particularly limited. In one example, the encapsulant 115 may surround at least a portion of each of the antenna 114 and the integrated circuit chip 111. For example, a portion of the antenna 114 or a portion of the integrated circuit chip 111 may be exposed to the outside without being encapsulated by the encapsulant 115. In another embodiment, an entirety of the antenna 114 or an entirety of the integrated circuit chip 111 may be encapsulated by the encapsulant 115.

In an embodiment, a portion of surface of the antenna 114 may be exposed to the outside without being encapsulated by the encapsulant 115. For example, as illustrated in FIG. 2, at least a portion (exposed area) of an upper surface of the antenna 114 may be exposed to the outside without being encapsulated by the encapsulant 115. The wireless signal may be radiated to a free space through the exposed area of the antenna 114.

In an embodiment, a parasitic antenna element (not shown) may be disposed on the exposed area of the antenna 114. The parasitic antenna element (not shown) may have various shapes such as a square, a circle, an ellipse, and an E, but the shape of the parasitic antenna element (not shown) is not limited thereto. A material of the encapsulant 115 is not particularly limited. For example, an insulating material may be used as the material of the encapsulant 115, and in this case, the insulating material may include a thermosetting resin such as an epoxy resin, a thermoplastic resin such as polyimide, or a resin in which the thermosetting resin or the thermoplastic resin is mixed with an inorganic filler or impregnated with a core material such as glass fibers (glass fiber, glass cloth, and glass fabric) together with the inorganic filler, for example, prepreg, Ajinomoto Build-up Film (ABF), FR-4, Bismaleimide Triazine (BT), or the like. If necessary, a photo imagable encapsulant (PIE) resin may be used as the material of the encapsulant 115. Alternatively, a known molding material such as an epoxy molding compound (EMC) may be used as the material of the encapsulant 115.

In an embodiment, when the antenna 114 is embodied as the dielectric resonator antenna, a dielectric constant of the antenna 114 may be greater than a dielectric constant of the encapsulant 115.

In an embodiment, the antenna layer 11 may further include at least one dummy chip 112 disposed around the antenna 114 or the integrated circuit chip 111 and encapsulated by the encapsulant 115. When the dummy chip 112 is disposed in the antenna layer 11, a content of the encapsulant 115 in the antenna layer 11 is relatively reduced. In a process of manufacturing the antenna-in-package 100, a phenomenon in which a portion of the antenna-in-package 100 is deformed, that is, warpage, may occur due to a difference between thermal expansion coefficients of the respective components included in the antenna-in-package 100. However, when the at least one dummy chip 112 is disposed in the antenna layer 11, warpage may be reduced in the process of manufacturing the antenna-in-package 100.

A material or a shape of the dummy chip 112 is not particularly limited. For example, the dummy chip 112 may be an integrated circuit in which hundreds to millions of elements are integrated into one chip. The dummy chip 112 may have any function as long as it may serve as a dummy. The dummy chip 112 may be electrically insulated from the antenna 114 or the integrated circuit chip 111.

The antenna 114, the integrated circuit chip 111, and the dummy chip 112 may share the same material with each other. For example, when the integrated circuit chip 111 is embodied as an CMOS-based chip, the antenna 114 and the dummy chip 112 may include silicon. When the dummy chip 112, the antenna 114 and the integrated circuit chip 111 shares the same material with each other, a difference between thermal expansion coefficients of the antenna 114, the integrated circuit chip 111, and the dummy chip 112 may be reduced, and thus, the warpage may be reduced during the manufacturing process of the antenna-in-package 100.

When the antenna layer 11 includes the dummy chip 112, the dummy chip 112 may be encapsulated by the encapsulant 115.

Referring back to the drawing, the redistribution layer 13 may include an insulating layer 121, a conductive pattern 122 disposed in the insulating layer 121 and electrically connected to the antenna 114 or the integrated circuit chip 111, and at least one contact pad 113 and 123 connected to the conductive pattern 122.

A material of the insulating layer 121 is not particularly limited. For example, the material of the insulating layer 121 may include a thermosetting resin such as an epoxy resin, a thermoplastic resin such as polyimide, a resin in which the thermosetting resin such as an epoxy resin or the thermoplastic resin such as polyimide is impregnated with a reinforcing material such as an inorganic filler, for example, ABF, FR-4, BT, PID resin, or the like. In another example, a known molding material such as EMC may be used as the material of the insulating layer 121.

The conductive pattern 122 is disposed in the insulating layer 121 and may be made of a conductive material. The material of the conductive pattern 122 is not particularly limited. For example, the material of the conductive pattern 122 may include copper (Cu), aluminum (Al), silver (Ag), tin (Sn), gold (Au), nickel (Ni), lead (Pb), titanium (Ti), or an alloy thereof.

The conductive pattern 122 may provide an electrical connection between the antenna 114 and the integrated circuit chip 111. That is, the antenna 114 and the integrated circuit chip 111 may be electrically connected to each other via the conductive pattern 122.

In an embodiment, the conductive pattern 122 may include a power feeding line 119 that is opening-coupled to a slot 118 disposed at a position corresponding to the antenna 114. Using this structure, an electrical signal or power may be supplied to the antenna 114. In addition, the opening-coupling structure has an advantage in that noise radiation from the power feeding line 119 is isolated from a radiation slot opening.

In an embodiment, a center of the antenna 114 may coincide with a center of the slot 118. According to this structure, strong coupling between the antenna 114 and the slot 118 may be ensured in an internal field.

In an embodiment, impedance matching may be achieved by positioning the antenna 114 to be offset from the slot 118.

A shape of the slot 118 may vary depending on a radiation mode, polarization, and geometric shape of the antenna 114. For example, the slot 118 may have various shapes such as a rectangular shape, a square shape, a circle shape, a C shape, and a cross shape. However, the shape of the slot 118 is not limited thereto. In another example, the slot 118 may have a loop opening structure. Examples of the power feeding line 119 may include a microstrip line or a coplanar waveguide. However, a type of the power feeding line 119 is not limited thereto.

In another embodiment, the antenna-in-package 100 may further include a through mold via (not shown) extending through at least a portion of the redistribution layer 13 and disposed at a position corresponding to a position of the antenna 114.

The contact pad 113 and 123 may be connected to one end of the conductive pattern 122. The contact pad 113 and 123 may be made of a conductive material in a similar manner to the conductive pattern 122. In an embodiment, the contact pad 113 and 123 may include the first contact pad 113 connected to one end of the conductive pattern 122 and electrically in contact with the integrated circuit chip 111, and the second contact pad 123 connected to one end of the conductive pattern 122 and electrically in contact with a solder ball 15. Accordingly, the conductive pattern 122 may provide an electrical connection between the first contact pad 113 and the second contact pad 123.

In an embodiment, the second contact pad 123 may be connected to the solder ball 15. The solder ball 15 may be made of a conductive material in a similar manner to the conductive pattern 122 or the contact pad 113 and 123. In an embodiment, a plurality of solder balls 15 may be disposed on a lower surface of the redistribution layer 13 and may be arranged in a form of a ball grid array (BGA). The solder ball 15 may be electrically connected to a contact via 17 disposed in a substrate 16. The contact via 17 may be electrically connected to a conductive pattern 18 disposed on one side of the substrate 16.

The substrate 16 may include the conductive pattern 18 and the contact via 17 electrically connected to the conductive pattern 18. The conductive pattern 18 may be electrically connected to any component. The substrate 16 may provide power and/or electrical signals for an operation of the antenna-in-package 100 to the antenna-in-package 100.

In the antenna-in-package 100 having the above-described structure, the redistribution layer 13 may provide a ground plane for the antenna 114. Accordingly, the radiation of the antenna 114 may be directed in a direction 130 toward a wider space.

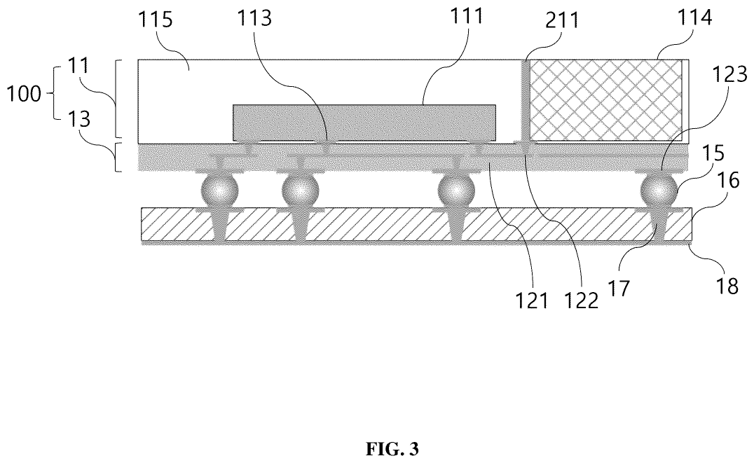

FIG. 3 is a longitudinal cross-sectional view of an antenna-in-package according to a second embodiment.

Referring to the drawing, the antenna-in-package 100 according to the second embodiment may include the antenna layer 11 and the redistribution layer 13.

The antenna layer 11 may include the one or more antennas 114 configured to transmit and receive a wireless signal, the integrated circuit chip 111 configured to control the antenna 114, and the encapsulant 115 configured to encapsulate at least a portion of each of the antenna 114 and the integrated circuit chip 111.

In an embodiment, the antenna 114 may be embodied as a dielectric resonator antenna including a dielectric having a predetermined dielectric constant and transmitting or receiving a wireless signal via resonance of the dielectric. For example, the antenna 114 may be a dielectric resonator antenna made of undoped silicon. In another example, the antenna 114 may be a dielectric resonator antenna made of a material having a dielectric constant of 11.7 and operating in a millimeter wave band. However, the type of the antenna 114 is not limited thereto.

In an embodiment, the antenna 114 may transmit and receive a wireless signal in the RF band. The shape of the antenna 114 is not particularly limited. For example, the antenna 114 may have a shape such as a cylinder, a polygonal box, a cone, a divided cylinder, a toroid, or a truncated pyramid. However, the shape of the antenna 114 is not limited thereto.

The antenna-in-package 100 may include one or more antennas 114. When the antenna-in-package 100 includes a plurality of antennas 114, the plurality of antennas 114 may be arranged according to a predetermined arrangement pattern. The plurality of antennas 114 may be arranged symmetrically or asymmetrically. The number or arrangement pattern of the antennas 114 is not particularly limited.

The integrated circuit chip 111 may control a wireless signal transmission or reception operation of the antenna 114. For example, the integrated circuit chip 111 may receive a wireless signal from the antenna 114 or may provide a wireless signal to the antenna 114.

In an embodiment, the integrated circuit chip 111 may be a RFIC capable of receiving a wireless signal in a RF band from the antenna 114 or providing a wireless signal in a RF band to the antenna 114. However, the type of the integrated circuit chip 111 is not limited thereto, and the integrated circuit chip 111 may be a different type of a chip therefrom. In another example, the integrated circuit chip 111 may be embodied as an CMOS chip for millimeter wave wireless communication.

The encapsulant 115 may protect the antenna 114 and the integrated circuit chip 111. An encapsulation form by the encapsulant is not particularly limited. In one example, the encapsulant 115 may surround at least a portion of each of the antenna 114 and the integrated circuit chip 111. For example, a portion of the antenna 114 or a portion of the integrated circuit chip 111 may be exposed to the outside without being encapsulated by the encapsulant 115. In another embodiment, an entirety of the antenna 114 or an entirety of the integrated circuit chip 111 may be encapsulated by the encapsulant 115.

In an embodiment, a portion of surface of the antenna 114 may be exposed to the outside without being encapsulated by the encapsulant 115. For example, as illustrated in FIG. 3, at least a portion (exposed area) of an upper surface of the antenna 114 may be exposed to the outside without being encapsulated by the encapsulant 115. The wireless signal may be radiated to a free space through the exposed area of the antenna 114.

A material of the encapsulant 115 is not particularly limited. For example, an insulating material may be used as the material of the encapsulant 115, and in this case, the insulating material may include a thermosetting resin such as an epoxy resin, a thermoplastic resin such as polyimide, or a resin in which the thermosetting resin or the thermoplastic resin is mixed with an inorganic filler or impregnated with a core material such as glass fibers (glass fiber, glass cloth, and glass fabric) together with the inorganic filler, for example, prepreg, Ajinomoto Build-up Film (ABF), FR-4, Bismaleimide Triazine (BT), or the like. If necessary, a photo imagable encapsulant (PIE) resin may be used as the material of the encapsulant 115. Alternatively, a known molding material such as an epoxy molding compound (EMC) may be used as the material of the encapsulant 115.

In an embodiment, when the antenna 114 is embodied as the dielectric resonator antenna, a dielectric constant of the antenna 114 may be greater than a dielectric constant of the encapsulant 115.

In an embodiment, although not shown, the antenna layer 11 may further include at least one dummy chip (not shown) disposed around the antenna 114 or the integrated circuit chip 111 and encapsulated by the encapsulant 115.

When the dummy chip (not shown) is disposed in the antenna layer 11, a content of the encapsulant 115 in the antenna layer 11 is relatively reduced. In a process of manufacturing the antenna-in-package 100, a phenomenon in which a portion of the antenna-in-package 100 is deformed, that is, warpage, may occur due to a difference between thermal expansion coefficients of the respective components included in the antenna-in-package 100. However, when the at least one dummy chip (not shown) is disposed in the antenna layer 11, warpage may be reduced in the process of manufacturing the antenna-in-package 100.

A material or a shape of the dummy chip (not shown) is not particularly limited. For example, the dummy chip (not shown) may be an integrated circuit in which hundreds to millions of elements are integrated into one chip. The dummy chip (not shown) may have any function as long as it may serve as a dummy. The dummy chip (not shown) may be electrically insulated from the antenna 114 or the integrated circuit chip 111.

The antenna 114, the integrated circuit chip 111, and the dummy chip (not shown) may share the same material with each other. For example, when the integrated circuit chip 111 is embodied as an CMOS-based chip, the antenna 114 and the dummy chip (not shown) may include silicon. When the dummy chip (not shown), the antenna 114 and the integrated circuit chip 111 shares the same material with each other, a difference between thermal expansion coefficients of the antenna 114, the integrated circuit chip 111, and the dummy chip (not shown) may be reduced, and thus, the warpage may be reduced during the manufacturing process of the antenna-in-package 100.

When the antenna layer 11 includes the dummy chip (not shown), the dummy chip (not shown) may be encapsulated by the encapsulant 115.

Referring back to the drawing, the redistribution layer 13 may include an insulating layer 121, a conductive pattern 122 disposed in the insulating layer 121 and electrically connected to the antenna 114 or the integrated circuit chip 111, and at least one contact pad 113 and 123 connected to the conductive pattern 122.

A material of the insulating layer 121 is not particularly limited. For example, the material of the insulating layer 121 may include a thermosetting resin such as an epoxy resin, a thermoplastic resin such as polyimide, a resin in which the thermosetting resin such as an epoxy resin or the thermoplastic resin such as polyimide is impregnated with a reinforcing material such as an inorganic filler, for example, ABF, FR-4, BT, PID resin, or the like. In another example, a known molding material such as EMC may be used as the material of the insulating layer 121.

The conductive pattern 122 is disposed in the insulating layer 121 and may be made of a conductive material. The material of the conductive pattern 122 is not particularly limited. For example, the material of the conductive pattern 122 may include copper (Cu), aluminum (Al), silver (Ag), tin (Sn), gold (Au), nickel (Ni), lead (Pb), titanium (Ti), or an alloy thereof.

The conductive pattern 122 may provide an electrical connection between the antenna 114 and the integrated circuit chip 111. That is, the antenna 114 and the integrated circuit chip 111 may be electrically connected to each other via the conductive pattern 122.

In an embodiment, although not shown, the conductive pattern 122 may include a power feeding line (not shown) that is opening-coupled to a slot disposed at a position corresponding to the antenna 114. Using this structure, an electrical signal or power may be supplied to the antenna 114. In addition, the opening-coupling structure has an advantage in that noise radiation from the power feeding line (not shown) is isolated from a radiation slot opening.

In an embodiment, the antenna layer 11 may further include a through mold via 211. The through mold via 211 may be electrically connected to each of the conductive pattern 122 and the antenna 114.

In the second embodiment AS shown in FIG. 3, the through mold via 211 may also be referred to as a mono-pole antenna coupled to the antenna 114. When the antenna 114 is embodied as the dielectric resonator antenna, the antenna 114 coupled to the through mold via 211 as shown in FIG. 3 may be referred to as a monopole-DRA antenna. The monopole-DRA antenna may achieve ultra-wide band (UWB) performance via mode fusion.

The through mold via 211 may be disposed adjacent to the antenna 114 as shown in FIG. 3, or may be formed to extend through the inside of the antenna 114. The position of the through mold via 211 may vary depending on an input impedance of the antenna 114.

The contact pad 113 and 123 may be connected to one end of the conductive pattern 122. The contact pad 113 and 123 may be made of a conductive material in a similar manner to the conductive pattern 122. In an embodiment, the contact pad 113 and 123 may include the first contact pad 113 connected to one end of the conductive pattern 122 and electrically in contact with the integrated circuit chip 111, and the second contact pad 123 connected to one end of the conductive pattern 122 and electrically in contact with a solder ball 15. Accordingly, the conductive pattern 122 may provide an electrical connection between the first contact pad 113 and the second contact pad 123.

In an embodiment, the second contact pad 123 may be connected to the solder ball 15. The solder ball 15 may be made of a conductive material in a similar manner to the conductive pattern 122 or the contact pad 113 and 123. In an embodiment, a plurality of solder balls 15 may be disposed on a lower surface of the redistribution layer 13 and may be arranged in a form of a ball grid array (BGA).

The solder ball 15 may be electrically connected to a contact via 17 disposed in a substrate 16. The contact via 17 may be electrically connected to a conductive pattern 18 disposed on one side of the substrate 16.

The substrate 16 may include the conductive pattern 18 and the contact via 17 electrically connected to the conductive pattern 18. The conductive pattern 18 may be electrically connected to any component. The substrate 16 may provide power and/or electrical signals for an operation of the antenna-in-package 100 to the antenna-in-package 100.

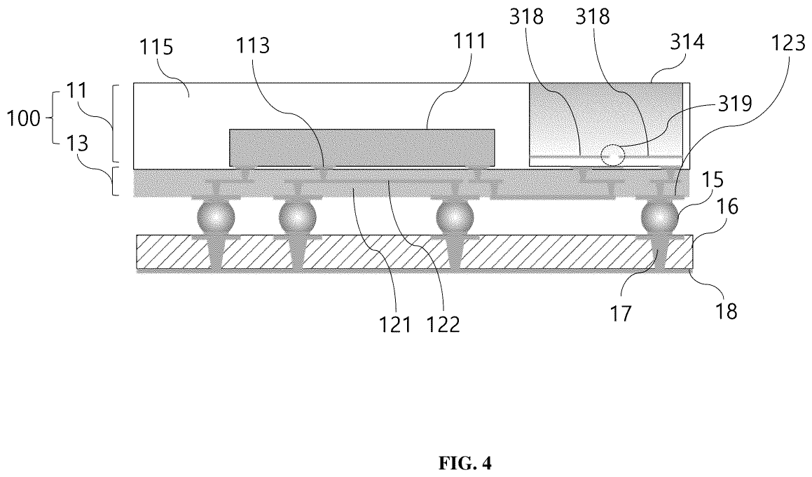

FIG. 4 is a longitudinal cross-sectional view of an antenna-in-package according to a third embodiment.

Referring to the drawing, the antenna-in-package 100 according to the second embodiment may include the antenna layer 11 and the redistribution layer 13.

The antenna layer 11 may include one or more antenna modules 314 configured to transmit and receive a wireless signal, the integrated circuit chip 111 configured to control the antenna module 314, and the encapsulant 115 configured to encapsulate at least a portion of each of the antenna module 314 and the integrated circuit chip 111.

In the third embodiment as illustrated in FIG. 4, the antenna module 314 may be an active semiconductor chip including a power feeding structure 318 and an antenna (not shown). The power feeding structure 318 may include at least one slot 319 for transmitting or receiving a wireless signal. An example of a substrate included in the active semiconductor chip may include a high resistance semiconductor substrate. However, the type of the substrate is not limited thereto. An example of the active semiconductor chip may include an RF CMOS or InP HEMT chip. However, the type of the active semiconductor chip is not limited thereto.

In an embodiment, the antenna module 314 may include a dielectric resonator antenna including a dielectric having a predetermined dielectric constant and transmitting or receiving a wireless signal via resonance of the dielectric. For example, the antenna module 314 may include a dielectric resonator antenna made of undoped silicon. In another example, the antenna module 314 may include a dielectric resonator antenna made of a material having a dielectric constant of 11.7 and operating in a millimeter wave band. However, the type of the antenna module 314 is not limited thereto. However, the type of the antenna included in the antenna module 314 is not limited thereto.

In an embodiment, the antenna module 314 may transmit and receive a wireless signal in the RF band. The shape of the antenna module 314 is not particularly limited. For example, the antenna module 314 may have a shape such as a cylinder, a polygonal box, a cone, a divided cylinder, a toroid, or a truncated pyramid. However, the shape of the antenna module 314 is not limited thereto.

The antenna-in-package 100 may include one or more antenna modules 314. When the antenna-in-package 100 includes a plurality of antenna modules 314, the plurality of antenna modules 314 may be arranged according to a predetermined arrangement pattern. The plurality of antenna modules 314 may be arranged symmetrically or asymmetrically. The number or arrangement pattern of the antenna modules 314 is not particularly limited.

The integrated circuit chip 111 may control a wireless signal transmission or reception operation of the antenna module 314. For example, the integrated circuit chip 111 may receive a wireless signal from the antenna module 314 or may provide a wireless signal to the antenna module 314.

In an embodiment, the integrated circuit chip 111 may be a RFIC capable of receiving a wireless signal in a RF band from the antenna module 314 or providing a wireless signal in a RF band to the antenna module 314. However, the type of the integrated circuit chip 111 is not limited thereto, and the integrated circuit chip 111 may be a different type of a chip therefrom. In another example, the integrated circuit chip 111 may be embodied as an CMOS chip for millimeter wave wireless communication.

The encapsulant 115 may protect the antenna module 314 and the integrated circuit chip 111. An encapsulation form by the encapsulant is not particularly limited. In one example, the encapsulant 115 may surround at least a portion of each of the antenna module 314 and the integrated circuit chip 111. For example, a portion of the antenna module 314 or a portion of the integrated circuit chip 111 may be exposed to the outside without being encapsulated by the encapsulant 115. In another embodiment, an entirety of the antenna module 314 or an entirety of the integrated circuit chip 111 may be encapsulated by the encapsulant 115.

In an embodiment, a portion of surface of the antenna module 314 may be exposed to the outside without being encapsulated by the encapsulant 115. For example, as illustrated in FIG. 4, at least a portion (exposed area) of an upper surface of the antenna module 314 may be exposed to the outside without being encapsulated by the encapsulant 115. The wireless signal may be radiated to a free space through the exposed area of the antenna module 314.

A material of the encapsulant 115 is not particularly limited. For example, an insulating material may be used as the material of the encapsulant 115, and in this case, the insulating material may include a thermosetting resin such as an epoxy resin, a thermoplastic resin such as polyimide, or a resin in which the thermosetting resin or the thermoplastic resin is mixed with an inorganic filler or impregnated with a core material such as glass fibers (glass fiber, glass cloth, and glass fabric) together with the inorganic filler, for example, prepreg, Ajinomoto Build-up Film (ABF), FR-4, Bismaleimide Triazine (BT), or the like. If necessary, a photo imagable encapsulant (PIE) resin may be used as the material of the encapsulant 115. Alternatively, a known molding material such as an epoxy molding compound (EMC) may be used as the material of the encapsulant 115.

In an embodiment, when the antenna module 314 includes the dielectric resonator antenna, a dielectric constant of the antenna of the antenna module 314 may be greater than a dielectric constant of the encapsulant 115.

In an embodiment, although not shown, the antenna layer 11 may further include at least one dummy chip (not shown) disposed around the antenna module 314 or the integrated circuit chip 111 and encapsulated by the encapsulant 115.

A material or a shape of the dummy chip (not shown) is not particularly limited. For example, the dummy chip (not shown) may be an integrated circuit in which hundreds to millions of elements are integrated into one chip. The dummy chip (not shown) may have any function as long as it may serve as a dummy. The dummy chip (not shown) may be electrically insulated from the antenna module 314 or the integrated circuit chip 111.

The antenna module 314, the integrated circuit chip 111, and the dummy chip (not shown) may share the same material with each other. For example, when the integrated circuit chip 111 is embodied as an CMOS-based chip, the antenna module 314 and the dummy chip (not shown) may include silicon. When the dummy chip (not shown), the antenna module 314 and the integrated circuit chip 111 shares the same material with each other, a difference between thermal expansion coefficients of the antenna module 314, the integrated circuit chip 111, and the dummy chip (not shown) may be reduced, and thus, the warpage may be reduced during the manufacturing process of the antenna-in-package 100.

When the antenna layer 11 includes the dummy chip (not shown), the dummy chip (not shown) may be encapsulated by the encapsulant 115.

Referring back to the drawing, the redistribution layer 13 may include an insulating layer 121, a conductive pattern 122 disposed in the insulating layer 121 and electrically connected to the antenna module 314 or the integrated circuit chip 111, and at least one contact pad 113 and 123 connected to the conductive pattern 122.

A material of the insulating layer 121 is not particularly limited. For example, the material of the insulating layer 121 may include a thermosetting resin such as an epoxy resin, a thermoplastic resin such as polyimide, a resin in which the thermosetting resin such as an epoxy resin or the thermoplastic resin such as polyimide is impregnated with a reinforcing material such as an inorganic filler, for example, ABF, FR-4, BT, PID resin, or the like. In another example, a known molding material such as EMC may be used as the material of the insulating layer 121.

The conductive pattern 122 is disposed in the insulating layer 121 and may be made of a conductive material. The material of the conductive pattern 122 is not particularly limited. For example, the material of the conductive pattern 122 may include copper (Cu), aluminum (Al), silver (Ag), tin (Sn), gold (Au), nickel (Ni), lead (Pb), titanium (Ti), or an alloy thereof.

The conductive pattern 122 may provide an electrical connection between the antenna module 314 and the integrated circuit chip 111. That is, the antenna module 314 and the integrated circuit chip 111 may be electrically connected to each other via the conductive pattern 122.

In an embodiment, although not shown, the conductive pattern 122 may include a power feeding line (not shown) that is opening-coupled to a slot disposed at a position corresponding to the antenna module 314. Using this structure, an electrical signal or power may be supplied to the antenna module 314. In addition, the opening-coupling structure has an advantage in that noise radiation from the power feeding line (not shown) is isolated from a radiation slot opening.

In another embodiment, the antenna layer 11 may further include a through mold via (not shown). The through mold via (not shown) may be electrically connected to each of the conductive pattern 122 and the antenna module 314.

The contact pad 113 and 123 may be connected to one end of the conductive pattern 122. The contact pad 113 and 123 may be made of a conductive material in a similar manner to the conductive pattern 122. In an embodiment, the contact pad 113 and 123 may include the first contact pad 113 connected to one end of the conductive pattern 122 and electrically in contact with the integrated circuit chip 111, and the second contact pad 123 connected to one end of the conductive pattern 122 and electrically in contact with a solder ball 15. Accordingly, the conductive pattern 122 may provide an electrical connection between the first contact pad 113 and the second contact pad 123.

In an embodiment, the second contact pad 123 may be connected to the solder ball 15. The solder ball 15 may be made of a conductive material in a similar manner to the conductive pattern 122 or the contact pad 113 and 123. In an embodiment, a plurality of solder balls 15 may be disposed on a lower surface of the redistribution layer 13 and may be arranged in a form of a ball grid array (BGA).

The solder ball 15 may be electrically connected to a contact via 17 disposed in a substrate 16. The contact via 17 may be electrically connected to a conductive pattern 18 disposed on one side of the substrate 16.

The substrate 16 may include the conductive pattern 18 and the contact via 17 electrically connected to the conductive pattern 18. The conductive pattern 18 may be electrically connected to any component. The substrate 16 may provide power and/or electrical signals for an operation of the antenna-in-package 100 to the antenna-in-package 100.

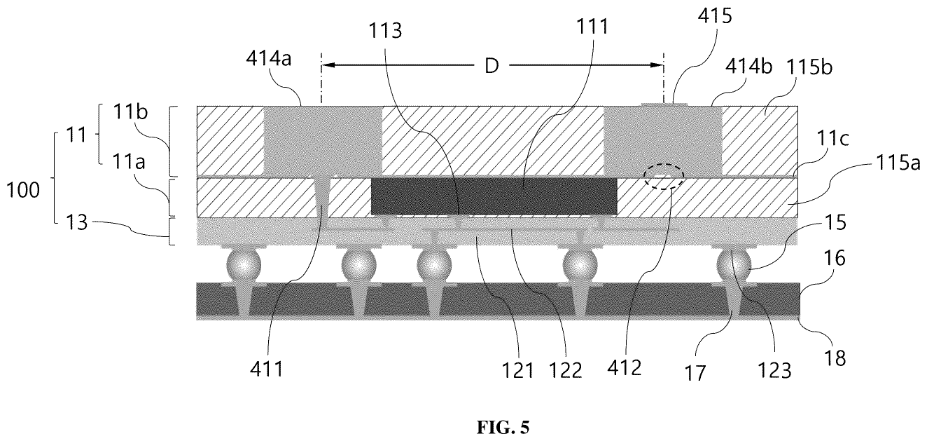

FIG. 5 is a longitudinal cross-sectional view of an antenna-in-package according to a fourth embodiment.

Referring to the drawing, the antenna-in-package 100 according to the fourth embodiment may include an antenna layer 11 and a redistribution layer 13. The antenna layer 11 may include a first layer 11a, a second layer 11b, and a metal layer 11c.

The first layer 11a may be disposed on one side of the redistribution layer 13. The first layer 11a may include an integrated circuit chip 111 that controls an antenna 414a and 414b and an encapsulant 115a that encapsulates at least a portion of the integrated circuit chip 111.

The metal layer 11c may be disposed on one side of the first layer 11a (or the one side of the second layer 11b). In other words, the metal layer 11c may be disposed between the first layer 11a and the second layer 11b. The metal layer 11c may provide a ground surface for the antenna 414a and 414b.

As illustrated in FIG. 5, when the integrated circuit chip 111 is disposed on ta lower surface of the metal layer 11c and the antenna 414a and 414b are disposed on an upper surface of the metal layer 11c, the integrated circuit chip 111 may be protected from electromagnetic interference generated in the process of transmitting and receiving the wireless signal by the antenna 414a and 414b.

The second layer 11b may be disposed on one side of the metal layer 11c.

The second layer 11b may include one or more antennas 414a and 414b for transmitting and receiving the wireless signal and an encapsulant 115b for encapsulating at least a portion of the antenna 414a and 414b.

As illustrated in FIG. 5, in the fourth embodiment, the antenna 414a and 414b and the integrated circuit chip 111 may be disposed at different layers. According to such a structure, a limitation on a distance D between the two antennas 414a and 414b may be reduced. For example, in a wireless application requiring a beam steering function, the structure of the antenna-in-package 100 of the fourth embodiment may provide a shorter distance D between the antennas 414a and 414b. Accordingly, a grating lobe may be suppressed such that a wider steering angle may be achieved, and a beam gain may be improved.

In an embodiment, the antenna 414a and 414b may be embodied as a dielectric resonator antenna including a dielectric having a predetermined dielectric constant and transmitting or receiving a wireless signal via resonance of the dielectric. For example, the antenna 414a and 414b may be a dielectric resonator antenna made of undoped silicon. In another example, the antenna 414a and 414b may be a dielectric resonator antenna made of a material having a dielectric constant of 11.7 and operating in a millimeter wave band. However, the type of the antenna 414a and 414b is not limited thereto.

In another embodiment, the antenna 414a and 414b may be embodied as an antenna module including an antenna and a power feeding structure. For example, the power feeding structure may include at least one slot for transmitting or receiving a wireless signal. An example of the substrate included in the antenna module may be a high resistance semiconductor substrate. However, the type of the substrate is not limited thereto. An example of the antenna module may include an RF CMOS or InP HEMT chip. However, the type of the antenna module is not limited thereto.

In an embodiment, the antenna 414a and 414b may transmit and receive a wireless signal in the RF band. The shape of the antenna 414a and 414b is not particularly limited. For example, the antenna 414a and 414b may have a shape such as a cylinder, a polygonal box, a cone, a divided cylinder, a toroid, or a truncated pyramid. However, the shape of the antenna 414a and 414b is not limited thereto.

The antenna-in-package 100 may include one or more antennas 414a and 414b. When the antenna-in-package 100 includes a plurality of antennas 414a and 414b, the plurality of antennas 414a and 414b may be arranged according to a predetermined arrangement pattern. The plurality of antennas 414a and 414b may be arranged symmetrically or asymmetrically. The number or arrangement pattern of the antennas 414a and 414b is not particularly limited.

The integrated circuit chip 111 may control a wireless signal transmission or reception operation of the antenna 414a and 414b. For example, the integrated circuit chip 111 may receive a wireless signal from the antenna 414a and 414b or may provide a wireless signal to the antenna 414a and 414b.

In an embodiment, the integrated circuit chip 111 may be a RFIC capable of receiving a wireless signal in a RF band from the antenna 414a and 414b or providing a wireless signal in a RF band to the antenna 414a and 414b. However, the type of the integrated circuit chip 111 is not limited thereto, and the integrated circuit chip 111 may be a different type of a chip therefrom. In another example, the integrated circuit chip 111 may be embodied as an CMOS chip for millimeter wave wireless communication.

The encapsulant 115a and 115b may protect the antenna 414a and 414b and the integrated circuit chip 111. An encapsulation form by the encapsulant is not particularly limited. In one example, the encapsulant 115a and 115b may surround at least a portion of each of the antenna 414a and 414b and the integrated circuit chip 111. For example, a portion of the antenna 414a and 414b or a portion of the integrated circuit chip 111 may be exposed to the outside without being encapsulated by the encapsulant 115a and 115b. In another embodiment, an entirety of the antenna 414a and 414b or an entirety of the integrated circuit chip 111 may be encapsulated by the encapsulant 115a and 115b.

In an embodiment, a portion of surface of the antenna 414a and 414b may be exposed to the outside without being encapsulated by the encapsulant 115b. For example, as illustrated in FIG. 5, at least a portion (exposed area) of an upper surface of the antenna 414a and 414b may be exposed to the outside without being encapsulated by the encapsulant 115b. The wireless signal may be radiated to a free space through the exposed area of the antenna 414a and 414b.

In an embodiment, a parasitic antenna element 415 may be disposed on the exposed area of the antenna 414a and 414b. The parasitic antenna element 415 may have various shapes such as a square, a circle, an ellipse, and an E. However, the shape of the parasitic antenna element 415 is not limited thereto.

When the antenna 414a and 414b is embodied as the dielectric resonator antenna, the resonance frequency of the parasitic antenna element 415 may be set to be different from the resonance frequency of the antenna 414a and 414b. Accordingly, a bandwidth of the antenna 414a and 414b may be wider.

A material of the encapsulant 115a and 115b is not particularly limited. For example, an insulating material may be used as the material of the encapsulant 115a and 115b, and in this case, the insulating material may include a thermosetting resin such as an epoxy resin, a thermoplastic resin such as polyimide, or a resin in which the thermosetting resin or the thermoplastic resin is mixed with an inorganic filler or impregnated with a core material such as glass fibers (glass fiber, glass cloth, and glass fabric) together with the inorganic filler, for example, prepreg, Ajinomoto Build-up Film (ABF), FR-4, Bismaleimide Triazine (BT), or the like. If necessary, a photo imagable encapsulant (PIE) resin may be used as the material of the encapsulant 115a and 115b. Alternatively, a known molding material such as an epoxy molding compound (EMC) may be used as the material of the encapsulant 115a and 115b.

In an embodiment, when the antenna 414a and 414b is embodied as the dielectric resonator antenna, a dielectric constant of the antenna 414a and 414b may be greater than a dielectric constant of the encapsulant 115.

In an embodiment, although not shown, the second layer 11b of the antenna layer 11 may further include at least one dummy chip (not shown) disposed around the antenna 414a and 414b and encapsulated by the encapsulant 115b.

A material or a shape of the dummy chip (not shown) is not particularly limited. For example, the dummy chip (not shown) may be an integrated circuit in which hundreds to millions of elements are integrated into one chip. The dummy chip (not shown) may have any function as long as it may serve as a dummy. The dummy chip (not shown) may be electrically insulated from the antenna 414a and 414b or the integrated circuit chip 111.

The antenna 414a and 414b, the integrated circuit chip 111, and the dummy chip (not shown) may share the same material with each other. For example, when the integrated circuit chip 111 is embodied as an CMOS-based chip, the antenna 414a and 414b and the dummy chip (not shown) may include silicon. When the dummy chip (not shown), the antenna 414a and 414b and the integrated circuit chip 111 shares the same material with each other, a difference between thermal expansion coefficients of the antenna 414a and 414b, the integrated circuit chip 111, and the dummy chip (not shown) may be reduced, and thus, the warpage may be reduced during the manufacturing process of the antenna-in-package 100.

When the second layer 11b of the antenna layer 11 includes the dummy chip (not shown), the dummy chip (not shown) may be encapsulated by the encapsulant 115b.

Referring back to the drawing, the redistribution layer 13 may include an insulating layer 121, a conductive pattern 122 disposed in the insulating layer 121 and electrically connected to the antenna 414a and 414b or the integrated circuit chip 111, and at least one contact pad 113 and 123 connected to the conductive pattern 122.

A material of the insulating layer 121 is not particularly limited. For example, the material of the insulating layer 121 may include a thermosetting resin such as an epoxy resin, a thermoplastic resin such as polyimide, a resin in which the thermosetting resin such as an epoxy resin or the thermoplastic resin such as polyimide is impregnated with a reinforcing material such as an inorganic filler, for example, ABF, FR-4, BT, PID resin, or the like. In another example, a known molding material such as EMC may be used as the material of the insulating layer 121.

The conductive pattern 122 is disposed in the insulating layer 121 and may be made of a conductive material. The material of the conductive pattern 122 is not particularly limited. For example, the material of the conductive pattern 122 may include copper (Cu), aluminum (Al), silver (Ag), tin (Sn), gold (Au), nickel (Ni), lead (Pb), titanium (Ti), or an alloy thereof.

The conductive pattern 122 may provide an electrical connection between the antenna 414a and 414b and the integrated circuit chip 111. That is, the antenna 414a and 414b and the integrated circuit chip 111 may be electrically connected to each other via the conductive pattern 122.

In an embodiment, although not shown, the conductive pattern 122 may include a power feeding line (not shown) that is opening-coupled to a slot 412 defined at a position corresponding to the antenna 414b. Using this structure, an electrical signal or power may be supplied to the antenna 414b. In addition, the opening-coupling structure has an advantage in that noise radiation from the power feeding line (not shown) is isolated from a radiation slot opening.

In an embodiment, the antenna layer 11 may further include a through mold via (not shown). The through mold via (not shown) may be electrically connected to each of the conductive pattern 122 and the antenna 414a and 414b.

The contact pad 113 and 123 may be connected to one end of the conductive pattern 122. The contact pad 113 and 123 may be made of a conductive material in a similar manner to the conductive pattern 122. In an embodiment, the contact pad 113 and 123 may include the first contact pad 113 connected to one end of the conductive pattern 122 and electrically in contact with the integrated circuit chip 111, and the second contact pad 123 connected to one end of the conductive pattern 122 and electrically in contact with a solder ball 15. Accordingly, the conductive pattern 122 may provide an electrical connection between the first contact pad 113 and the second contact pad 123.

In an embodiment, the second contact pad 123 may be connected to the solder ball 15. The solder ball 15 may be made of a conductive material in a similar manner to the conductive pattern 122 or the contact pad 113 and 123. In an embodiment, a plurality of solder balls 15 may be disposed on a lower surface of the redistribution layer 13 and may be arranged in a form of a ball grid array (BGA).

The solder ball 15 may be electrically connected to a contact via 17 disposed in a substrate 16. The contact via 17 may be electrically connected to a conductive pattern 18 disposed on one side of the substrate 16.

The substrate 16 may include the conductive pattern 18 and the contact via 17 electrically connected to the conductive pattern 18. The conductive pattern 18 may be electrically connected to any component. The substrate 16 may provide power and/or electrical signals for an operation of the antenna-in-package 100 to the antenna-in-package 100.

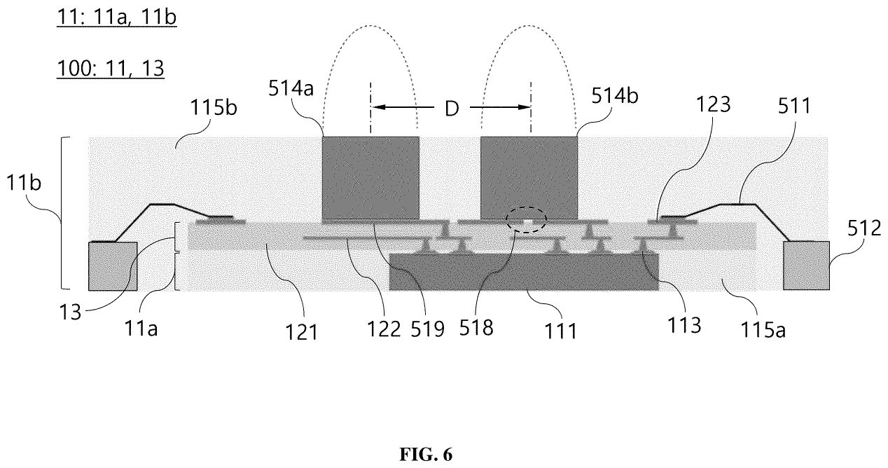

FIG. 6 is a longitudinal cross-sectional view of an antenna-in-package according to a fifth embodiment.

Referring to the drawing, the antenna-in-package 100 according to the fifth embodiment may include an antenna layer 11 and a redistribution layer 13. The antenna layer 11 may include a first layer 11a and a second layer 11b.

The first layer 11a may be disposed on one side of the redistribution layer 13. The first layer 11a may include an integrated circuit chip 111 that controls an antenna 514a and 514b and an encapsulant 115a that encapsulates at least a portion of the integrated circuit chip 111.

The second layer 11b may be disposed to surround other side of the redistribution layer 13 and at least a portion of the first layer 11a. The second layer 11b may include one or more antennas 514a and 514b for transmitting and receiving the wireless signal and an encapsulant 115b for encapsulating at least a portion of the antenna 514a and 514b.

In an embodiment, the antenna 514a and 514b may be embodied as a dielectric resonator antenna including a dielectric having a predetermined dielectric constant and transmitting or receiving a wireless signal via resonance of the dielectric. For example, the antenna 514a and 514b may be a dielectric resonator antenna made of undoped silicon. In another example, the antenna 514a and 514b may be a dielectric resonator antenna made of a material having a dielectric constant of 11.7 and operating in a millimeter wave band. However, the type of the antenna 514a and 514b is not limited thereto.

In another embodiment, the antenna 514a and 514b may be embodied as an antenna module including an antenna and a power feeding structure. For example, the power feeding structure may include at least one slot for transmitting or receiving a wireless signal. An example of the substrate included in the antenna module may be a high resistance semiconductor substrate. However, the type of the substrate is not limited thereto. An example of the antenna module may include an RF CMOS or InP HEMT chip. However, the type of the antenna module is not limited thereto.

In an embodiment, the antenna 514a and 514b may transmit and receive a wireless signal in the RF band. The shape of the antenna 514a and 514b is not particularly limited. For example, the antenna 514a and 514b may have a shape such as a cylinder, a polygonal box, a cone, a divided cylinder, a toroid, or a truncated pyramid. However, the shape of the antenna 514a and 514b is not limited thereto.

The antenna-in-package 100 may include one or more antennas 514a and 514b. When the antenna-in-package 100 includes a plurality of antennas 514a and 514b, the plurality of antennas 514a and 514b may be arranged according to a predetermined arrangement pattern. The plurality of antennas 514a and 514b may be arranged symmetrically or asymmetrically. The number or arrangement pattern of the antennas 514a and 514b is not particularly limited.

The integrated circuit chip 111 may control a wireless signal transmission or reception operation of the antenna 514a and 514b. For example, the integrated circuit chip 111 may receive a wireless signal from the antenna 514a and 514b or may provide a wireless signal to the antenna 514a and 514b.

In an embodiment, the integrated circuit chip 111 may be a RFIC capable of receiving a wireless signal in a RF band from the antenna 514a and 514b or providing a wireless signal in a RF band to the antenna 514a and 514b. However, the type of the integrated circuit chip 111 is not limited thereto, and the integrated circuit chip 111 may be a different type of a chip therefrom. In another example, the integrated circuit chip 111 may be embodied as an CMOS chip for millimeter wave wireless communication.

The encapsulant 115a and 115b may protect the antenna 514a and 514b and the integrated circuit chip 111. An encapsulation form by the encapsulant is not particularly limited. In one example, the encapsulant 115a and 115b may surround at least a portion of each of the antenna 514a and 514b and the integrated circuit chip 111. For example, a portion of the antenna 514a and 514b or a portion of the integrated circuit chip 111 may be exposed to the outside without being encapsulated by the encapsulant 115a and 115b. In another embodiment, an entirety of the antenna 514a and 514b or an entirety of the integrated circuit chip 111 may be encapsulated by the encapsulant 115a and 115b.

In an embodiment, a portion of surface of the antenna 514a and 514b may be exposed to the outside without being encapsulated by the encapsulant 115. For example, as illustrated in FIG. 6, at least a portion (exposed area) of an upper surface of the antenna 514a and 514b may be exposed to the outside without being encapsulated by the encapsulant 115. The wireless signal may be radiated to a free space through the exposed area of the antenna 514a and 514b.

In an embodiment, a parasitic antenna element (not shown) may be disposed on the exposed area of the antenna 514a and 514b. The parasitic antenna element (not shown) may have various shapes such as a square, a circle, an ellipse, and an E. However, the shape of the parasitic antenna element (not shown) is not limited thereto.

When the antenna 514a and 514b is embodied as the dielectric resonator antenna, the resonance frequency of the parasitic antenna element (not shown) may be set to be different from the resonance frequency of the antenna 514a and 514b. Accordingly, a bandwidth of the antenna 514a and 514b may be wider.

A material of the encapsulant 115 and 115b is not particularly limited. For example, an insulating material may be used as the material of the encapsulant 115a and 115b, and in this case, the insulating material may include a thermosetting resin such as an epoxy resin, a thermoplastic resin such as polyimide, or a resin in which the thermosetting resin or the thermoplastic resin is mixed with an inorganic filler or impregnated with a core material such as glass fibers (glass fiber, glass cloth, and glass fabric) together with the inorganic filler, for example, prepreg, Ajinomoto Build-up Film (ABF), FR-4, Bismaleimide Triazine (BT), or the like. If necessary, a photo imagable encapsulant (PIE) resin may be used as the material of the encapsulant 115a and 115b. Alternatively, a known molding material such as an epoxy molding compound (EMC) may be used as the material of the encapsulant 115a and 115b.

In an embodiment, when the antenna 514a and 514b is embodied as the dielectric resonator antenna, a dielectric constant of the antenna 514a and 514b may be greater than a dielectric constant of the encapsulant 115.

In an embodiment, although not shown, the second layer 11b of the antenna layer 11 may further include at least one dummy chip (not shown) disposed around the antenna 514a and 514b or the integrated circuit chip 111 and encapsulated by the encapsulant 115b.

A material or a shape of the dummy chip (not shown) is not particularly limited. For example, the dummy chip (not shown) may be an integrated circuit in which hundreds to millions of elements are integrated into one chip. The dummy chip (not shown) may have any function as long as it may serve as a dummy. The dummy chip (not shown) may be electrically insulated from the antenna 514a and 514b or the integrated circuit chip 111.

The antenna 514a and 514b, the integrated circuit chip 111, and the dummy chip (not shown) may share the same material with each other. For example, when the integrated circuit chip 111 is embodied as an CMOS-based chip, the antenna 514a and 514b and the dummy chip (not shown) may include silicon. When the dummy chip (not shown), the antenna 514a and 514b and the integrated circuit chip 111 shares the same material with each other, a difference between thermal expansion coefficients of the antenna 514a and 514b, the integrated circuit chip 111, and the dummy chip (not shown) may be reduced, and thus, the warpage may be reduced during the manufacturing process of the antenna-in-package 100.

When the antenna layer 11 includes the dummy chip (not shown), the dummy chip (not shown) may be encapsulated by the encapsulant 115b.

Referring back to the drawing, the redistribution layer 13 may include an insulating layer 121, a conductive pattern 122 disposed in the insulating layer 121 and electrically connected to the antenna 514a and 514b or the integrated circuit chip 111, and at least one contact pad 113 and 123 connected to the conductive pattern 122.

A material of the insulating layer 121 is not particularly limited. For example, the material of the insulating layer 121 may include a thermosetting resin such as an epoxy resin, a thermoplastic resin such as polyimide, a resin in which the thermosetting resin such as an epoxy resin or the thermoplastic resin such as polyimide is impregnated with a reinforcing material such as an inorganic filler, for example, ABF, FR-4, BT, PID resin, or the like. In another example, a known molding material such as EMC may be used as the material of the insulating layer 121.

The conductive pattern 122 is disposed in the insulating layer 121 and may be made of a conductive material. The material of the conductive pattern 122 is not particularly limited. For example, the material of the conductive pattern 122 may include copper (Cu), aluminum (Al), silver (Ag), tin (Sn), gold (Au), nickel (Ni), lead (Pb), titanium (Ti), or an alloy thereof.

The conductive pattern 122 may provide an electrical connection between the antenna 514a and 514b and the integrated circuit chip 111. That is, the antenna 514a and 514b and the integrated circuit chip 111 may be electrically connected to each other via the conductive pattern 122.

In an embodiment, the conductive pattern 122 may include a power feeding structure 519 disposed to be in electrical contact with the antenna 514a. An example of the power feeding structure 519 may include a rectangular patch, a circular patch, and an open stub. However, the type of the feeding structure 519 is not limited thereto.

In another embodiment, although not shown, the conductive pattern 122 may include a power feeding line (not shown) that is opening-coupled to a slot 518 defined at a position corresponding to the antenna 514b. Using this structure, an electrical signal or power may be supplied to the antenna 514b. In addition, the opening-coupling structure has an advantage in that noise radiation from the power feeding line (not shown) is isolated from a radiation slot opening.

In another embodiment, the antenna layer 11 may further include a through mold via (not shown). The through mold via (not shown) may be electrically connected to each of the conductive pattern 122 and the antenna 514a and 514b.

The contact pad 113 and 123 may be connected to one end of the conductive pattern 122. The contact pad 113 and 123 may be made of a conductive material in a similar manner to the conductive pattern 122. In an embodiment, the contact pad 113 and 123 may include the first contact pad 113 connected to one end of the conductive pattern 122 and electrically in contact with the integrated circuit chip 111, and the second contact pad 123 connected to one end of the conductive pattern 122 and electrically in contact with a solder ball 15. Accordingly, the conductive pattern 122 may provide an electrical connection between the first contact pad 113 and the second contact pad 123.

A wire 511 may be electrically connected to an external port 512 made of a metal material. The external port 512 may be electrically connected to an external power source. Accordingly, power supplied from the external power source may be supplied to the integrated circuit chip 111 or the antenna 514a and 514b via the external port 512.

According to the fifth embodiment illustrated in FIG. 6, the limitation on the distance D between the two antennas 514a and 514b may be alleviated. For example, in a wireless application requiring a beam steering function, the antenna-in-package 100 structure of the fifth embodiment may provide a shorter distance D between the antennas 514a and 514b. Accordingly, the grating lobe may be suppressed such that a wider steering angle may be achieved, and a beam gain may be improved.

As described above, the antenna-in-package according to embodiments of the present disclosure may be manufactured in a form of a fan-out package including the antenna layer and the redistribution layer.

Although the present disclosure has been described above with reference to the accompanying drawings, the present disclosure is not limited to the embodiments disclosed herein and the drawings, and it is obvious that various modifications may be made thereto by those skilled in the art within the scope of the technical idea of the present disclosure. In addition, although the effects based on the configuration of the present disclosure are not explicitly described and illustrated in the description of the embodiment of the present disclosure above, it is obvious that predictable effects from the configuration should also be recognized.

What is claimed is:

1. An antenna-in-package comprising:
an antenna layer including:
an antenna configured to transmit and receive a wireless signal;
an integrated circuit chip configured to control the antenna; and
an encapsulant configured to encapsulate at least a portion of each of the antenna and the integrated circuit chip; and
a redistribution layer including:
an insulating layer; and
a conductive pattern disposed in the insulating layer and electrically connected to the antenna or the integrated circuit chip.

2. The antenna-in-package of claim 1, wherein the antenna layer further includes at least one dummy chip disposed around the antenna or the integrated circuit chip and encapsulated by the encapsulant.

3. The antenna-in-package of claim 1, wherein the antenna and the integrated circuit chip are electrically connected to each other via the conductive pattern.

4. The antenna-in-package of claim 1, wherein the conductive pattern includes a power feeding line opening-coupled to a slot disposed at a position corresponding to a position of the antenna.

5. The antenna-in-package of claim 1, wherein the antenna-in-package further comprises a contact pad connected to the conductive pattern,
wherein the contact pad is connected to a solder ball,
wherein the solder ball is electrically connected to a substrate.

6. The antenna-in-package of claim 1, wherein the antenna includes a dielectric resonator antenna.

7. The antenna-in-package of claim 1, wherein the antenna layer further includes a through mold via electrically connected to each of the conductive pattern and the antenna.

8. The antenna-in-package of claim 1, wherein the antenna is an active semiconductor chip including a power feed structure and an antenna.

9. The antenna-in-package of claim 1, wherein the antenna layer includes:
a first layer disposed on one side of the redistribution layer and including the integrated circuit chip and the encapsulant;
a metal layer disposed on one side of the first layer; and
a second layer disposed on one side of the metal layer and including the antenna and the encapsulant.

10. The antenna-in-package of claim 9, wherein the antenna-in-package further comprises a through mold via extending through at least a portion of the redistribution layer and the first layer and disposed at a position corresponding to a position of the antenna.

11. The antenna-in-package of claim 1, wherein the antenna includes an exposed area not covered with the encapsulant and exposed to an outside.

12. The antenna-in-package of claim 11, wherein the antenna layer further includes a parasitic antenna element disposed on the exposed area.

13. The antenna-in-package of claim 1, wherein the antenna layer includes:
a first layer disposed on one side of the redistribution layer and including the integrated circuit chip and the encapsulant; and
a second layer disposed to surround other side of the redistribution layer and at least a portion of the first layer and including the antenna and the encapsulant.

14. The antenna-in-package of claim 13, wherein the antenna-in-package further comprises a contact pad connected to the conductive pattern,
wherein the second layer further includes an external port electrically connected to the contact pad.

15. An antenna-in-package comprising:
an antenna configured to transmit and receive a wireless signal;
an integrated circuit chip configured to control the antenna; and
a conductive pattern electrically connected to the antenna or the integrated circuit chip,
wherein the conductive pattern is disposed in an insulating layer.

16. The antenna-in-package of claim 15, wherein the antenna and the integrated circuit chip are disposed in an antenna layer,
wherein the insulating layer and the conductive pattern are disposed in a redistribution layer.

17. The antenna-in-package of claim 15, wherein the antenna-in-package further comprises an encapsulant configured to encapsulate at least a portion of each of the antenna and the integrated circuit chip.

18. The antenna-in-package of claim 17, wherein the antenna-in-package further comprises at least one dummy chip disposed around the antenna or the integrated circuit chip and encapsulated by the encapsulant.

19. The antenna-in-package of claim 15, wherein the antenna and the integrated circuit chip are electrically connected to each other via the conductive pattern.

20. The antenna-in-package of claim 15, wherein the conductive pattern includes a power feeding line opening-coupled to a slot disposed at a position corresponding to a position of the antenna.

21. The antenna-in-package of claim 15, wherein the antenna-in-package further comprises a contact pad connected to the conductive pattern,
wherein the contact pad is connected to a solder ball,
wherein the solder ball is electrically connected to a substrate.

22. The antenna-in-package of claim 15, wherein the antenna includes a dielectric resonator antenna.

23. The antenna-in-package of claim 15, wherein the antenna-in-package further comprises a through mold via electrically connected to each of the conductive pattern and the antenna.

24. The antenna-in-package of claim 15, wherein the antenna is an active semiconductor chip including a power feed structure and an antenna.

25. The antenna-in-package of claim 16, wherein the antenna layer includes:
a first layer disposed on one side of the redistribution layer and including the integrated circuit chip;
a metal layer disposed on one side of the first layer; and
a second layer disposed on one side of the metal layer and including the antenna.

26. The antenna-in-package of claim 25, wherein the antenna-in-package further comprises a through mold via extending through at least a portion of the redistribution layer and the first layer and disposed at a position corresponding to a position of the antenna.

27. The antenna-in-package of claim 18, wherein the antenna includes an exposed area not covered with the encapsulant and exposed to an outside.

28. The antenna-in-package of claim 27, wherein the antenna layer further includes a parasitic antenna element disposed on the exposed area.

29. The antenna-in-package of claim 16, wherein the antenna layer includes:
a first layer disposed on one side of the redistribution layer and including the integrated circuit chip; and
a second layer disposed to surround other side of the redistribution layer and at least a portion of the first layer and including the antenna.

30. The antenna-in-package of claim 29, wherein the antenna-in-package further comprises a contact pad connected to the conductive pattern,
wherein the second layer further includes an external port electrically connected to the contact pad.
